(19) United States
(12) Patent Application Publication
(10) Pub. No.: US 2024/0395651 A1
(43) Pub. Date: Nov. 28, 2024

(54) POWER MODULE HAVING SEMICONDUCTOR COMPONENTS AND INCORPORATING A TEMPERATURE SENSOR, AND ASSOCIATED MANUFACTURING METHOD

(71) Applicant: SAFRAN, PARIS (FR)

(72) Inventors: Rabih KHAZAKA, MOISSY-CRAMAYEL (FR); Baptiste Joël Christian FEDI, MOISSY-CRAMAYEL (FR); Nassim SALHI, MOISSY-CRAMAYEL (FR); Minh Chau PHAN HUY, MOISSY-CRAMAYEL (FR)

(21) Appl. No.: 18/704,586

(22) PCT Filed: Oct. 26, 2022
(86) PCT No.: PCT/FR2022/052038

§ 371 Date: Apr. 25, 2024

(30) Foreign Application Priority Data
Oct. 26, 2021 (FR) FR2111366

(51) Int. Cl. H01L 23/36; G01K 7/02; G01K 11/3206; H01L 21/48; H01L 23/00; H01L 23/057; H01L 23/498; H01L 23/538; H01L 25/00; H01L 25/065

(52) U.S. Cl. CPC H01L 23/36; G01K 7/02; G01K 11/3206; H01L 21/4882; H01L 23/538; H01L 25/0655; H01L 25/50; H01L 23/057; H01L 23/49811; H01L 24/48

(57) ABSTRACT

A power module includes a plurality of semiconductor-based power components and a substrate having an upper metallization receiving the components and a lower metallization opposite to the upper metallization. Optionally, a baseplate may be fixed to the lower metallization of the substrate. A metal structure is in direct contact with a lower surface defined by the either optional baseplate or the substrate, on the side opposite the components. The power module includes at least one elongated temperature sensor, at least partially immersed in the metal structure and spreading parallel to the lower surface.

### FIELD OF THE INVENTION

The invention relates to the field of electric power modules comprising semiconductor components. Such modules are in particular intended for the aeronautic field.

### DESCRIPTION OF RELATED ART

FIG. 1 shows a power module 1 according to the state-of-the-art. The power module 1 comprises a substrate 3 comprising an upper surface 5 receiving the semiconductor-based power components 7.

The components 7 are for example power switches (in particular insulated gate field-effect transistors or insulated gate bipolar transistors), connected to each other by cabling 9 and connected to connectors 11 themselves connected to a controller card (not shown) configured for driving said components 7.

The substrate 3 is for example a ceramic substrate, which comprises an insulating ceramic layer 13 separating an upper metallization 15, on which the components are brazed 5, from a lower metallization layer 17.

A baseplate 19 is brazed on the lower metallization 17 by an upper surface 20 of said baseplate 19, and a case 21 is attached to said metal baseplate 19 and in order to cover over the upper metallization 15 and the components 5. Connectors 11 pass through the case 21.

In order to have satisfactory thermal dissipation for the power module 1, a radiator 23 is attached to a lower surface 24 of the baseplate 19, to the lower surface 9, via a layer of thermal interface material 25 covering said lower surface 9.

In fact, because of imperfections therein, the power components 5 are the site of Joule effect thermal losses and therefore represent a significant heat source.

During operation of the power module 1, the electrical properties of the components 3 may vary in different ways (because of premature aging of certain components, manufacturing defects, etc.) introducing a wide disparity. This disparity can be seen as dissipated power which can be higher in some components thus leading to increases in local temperatures.

Additionally, during lifecycles of the module, thermomechanical stresses can lead to the formation and propagation of cracks in the structure thereof. These cracks can occur in the solder between the components 5 and the substrate 3, in the substrate 3 or in the solder between the substrate 3 and the baseplate 19. It causes an increase in the thermal resistance of the component under which the crack propagates and, consequently, a disparity of the temperature between the components. If these local temperature deviations are not quickly detected, they can lead to the thermal runaway of the module, resulting in the total failure thereof.

Solutions have been developed employing temperature sensors in order to track temperature elevations in the power module during operation thereof and thus to prevent overheating.

The incorporation of such a sensor directly into the semiconductor component limits the possibilities to a small number of available components on the market and greatly reduces the possibilities for adapting the power modules, which must be made to order, which leads to high prices.

The attachment of the sensor onto the component itself or near it on the substrate can have an impact on the electrical performance of the component, has only a limited reliability over the thermal cycles of the module, and does not show a very good sensitivity to the cracking taking place under the component.

### BRIEF SUMMARY OF THE INVENTION

The invention aims to remedy these disadvantages, by improving the control of the temperature in the power module without notably reducing the effectiveness of the thermal dissipation nor disturbing the operation of the module.

For this purpose, the subject matter of the invention is a power module comprising:
a plurality of semiconductor-based power components;
a substrate comprising an upper metallization receiving the components and a lower metallization opposite to the upper metallization;
optionally, a baseplate fixed to the lower metallization of the substrate;
a metal structure in direct contact with a lower surface defined by the baseplate or the substrate, on the side opposite the components;
a metal structure in direct contact with the lower surface; and
at least one elongated temperature sensor, at least partially immersed in the metal structure and spreading parallel to the lower surface;
wherein the metal structure is formed by electrodeposition on the lower surface and the elongated sensor.

With such a power module, the temperature of each component can be tracked allowing an improved detection and localization of thermal problems in the power module. The number of sensors needed for tracking all the components is reduced, and the sensors are immersed in the metallic structure, which improves the precision of the temperature measurement and greatly reduces the impact thereof on the thermal dissipation.

Further, the metal structure electroformed directly on the lower surface and the sensor form a continuous bond between said lower surface of the baseplate or the substrate on the one hand and the optical fiber on the other. The thermal and mechanical contact between the substrate or the baseplate and the optical fiber is thus continuous, without requiring an intermetallic connection interface which could disturb the temperature measurements. This also makes it possible to have a well-managed contact thermal resistance, unlike the case where the fiber is inserted in a space formed in the baseplate for example, thus allowing a reproducible and reliable measurement on the various components.

Additionally, in contrast to brazing, the electroforming method is done at low temperature (for example of order 60° C.), which limits the risks of breakdown of the optical fiber and the performance thereof.

The elongated sensor may spread alongside the components, in order to get the advantage of an improved sensitivity.

The structure may preferentially be implemented with copper, and alternatively with nickel, silver or any copper alloy compatible with electrodeposition method.

The metal structure may be a plate spreading over at least one part of the lower surface, where the plate has a thickness, measured perpendicular to said lower surface, that is substantially constant over the spread thereof.

Such a structure has a shape that is simple to fabricate, allowing a simplified and robust integration with the power module of this elongated sensor.

A radiator may be attached to the plate, on the side opposite the lower surface, for example by means of a layer of thermal interface material.

The metal structure may be a thermal radiator spreading over at least a portion of the lower surface.

With such a characteristic, the elongated sensor can be immersed in the structure of the radiator, which may be directly fabricated on the lower surface by electrodeposition.

The presence of the elongated sensor then disturbs the operation of the radiator very little, because of the tight integration thereof with the material.

Each elongated sensor may comprise an optical fiber, and in particular is a Bragg network optical fiber sensor or a Rayleigh backscattering optical fiber sensor.

Such a feature makes it possible to track the temperature at a plurality of points with a single elongated sensor, over the spread thereof, with a spatial resolution of order a millimeter.

Each optical fiber may have an outer diameter below 100 μm and have a suitable profile so that the optical fiber may have a radius of curvature less than or equal to 5 mm.

Such a characteristic makes it possible to follow a highly curved contour with the optical fiber without generating internal stresses disrupting the signal, in order to optimize the path thereof on the lower surface and to measure the temperature of as many components as possible with the fiber.

Each elongated sensor may comprise at least one thermocouple.

The power module may comprise as many thermocouples as power components, where each thermocouple is advantageously arranged alongside one of the components.

The invention also relates to a fabrication method of a power module like above, where the method comprises the following steps:
supplying a substrate having an upper metallization intended to receive semiconductor power components and a lower metallization opposite the upper metallization, and optionally a baseplate attached to the lower metallization of the substrate, where the baseplate or the substrate has a lower surface opposite the components;
placement of at least one elongated sensor on the lower surface;
formation of the metal structure by electrodeposition on the lower surface and on the elongated sensor.

The metal structure may be a plate of substantially constant thickness, where the method further comprises a step of attachment of a radiator to the plate on the side opposite the components.

The radiator may be attached by means of a layer of thermal interface material.

The metal structure may be a thermal radiator in which each elongated sensor is at least in part immersed, where the method comprises the steps of:
preparation, in particular by additive fabrication, of a preform suited for shaping the thermal radiator;
placement of the preform on the lower surface and, optionally, placement of a mask on a portion of the lower surface; and
subsequent to the formation of the metal structure, withdrawal of the preform and, as applicable, the mask.

The withdrawal of the mask and the preform may be done by chemical or thermal dissolution. The method is simple to practice unlike the case of the implementation of a channel for encasing the fiber under the components (in the substrate or the baseplate), with a width included between 100 μm and 500 μm. In practice, such a channel often has a fairly complex shape, in particular if components are not aligned, as is often the case, and requires costly technical steps in order to implement it (two plates to be brazed together, very high precision additive fabrication techniques, etc.).

The module resulting from the method according to the invention is thus more reliable because of eliminating the brazing used in order to make the attachment joints between the various constituent elements, not requiring creation of fragile intermetallic interfaces and not risking cracking in the solder.

### BRIEF DESCRIPTION OF THE DRAWINGS

FIG. 1 is a schematic section view of a power module according to the state-of-the-art;

FIG. 2 is a schematic section view of a power module according to a first embodiment of the invention;

FIG. 3 is a bottom, schematic section view of the power module from FIG. 1;

FIG. 3 is a bottom, schematic section view of a power module according to a second embodiment of the invention;

FIG. 5 is a schematic section view of a power module according to a third embodiment of the invention; and

FIG. 6 is a bottom, schematic section view of the power module from FIG. 5;

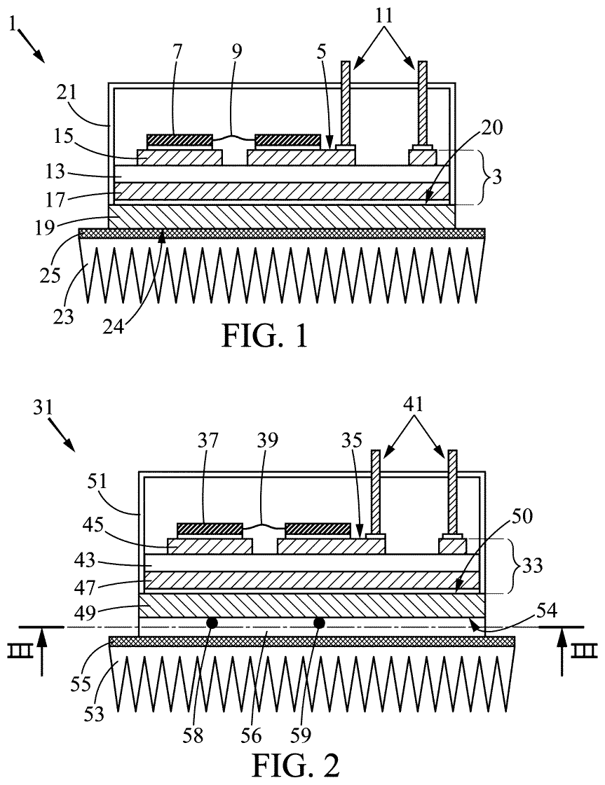

### DETAILED DESCRIPTION OF THE INVENTION

FIG. 2 shows a power module 31 according to the invention. Identically to what was described above, the power module 31 comprises a substrate 33 defining an upper surface 35 on which are brazed semiconductor electronic power components 37 connected by cabling 39 and connectors 41.

The substrate 33 comprises a ceramic layer 43 spreading between an upper metallization 45 on which are brazed the components 37 and connectors 41, and a lower metallization 47.

The lower metallization 47 is brazed to a metal baseplate 49 which carries a case 51 acting to cover and protect the components 37.

The baseplate 49 has an upper surface 50 on which is brazed the substrate and a lower surface 54 which spreads from the side opposite the substrate 33.

The metal structure 56 extends in direct contact with the lower surface 54 of the baseplate 49. The metal structure 56 is, in the first embodiment, a substantially rectangular metal plate of copper deposited on the lower surface 54 by electroforming.

Alternatively, the metal structure 56 may be made of nickel, silver, copper alloy or any other metal compatible with electrodeposition.

Said metal plate has a substantially constant thickness over its spread, measured perpendicular to the lower surface 54, for example included between 10 μm and 10 mm.

The power module 31 comprises at least one elongated temperature sensor 58, at least in part immersed in the metal structure 56 and spreading along the lower surface 54.

The elongated sensor 58 comprises at least one elongated part which spreads along a curved line through the metal structure 56.

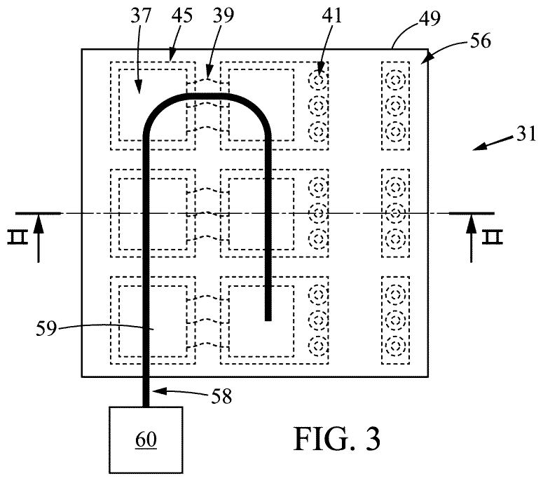

In the first embodiment, the elongated sensor 58 is a fiber-optic temperature sensor which comprises an optical fiber 59, immersed in the metal structure 56 and a control module 60 shown in FIG. 3 which is away from said metal structure 56.

Each optical fiber 59 is for example surrounded by a copper capillary which is itself incorporated in the metal structure 56 during formation thereof by electrodeposition.

The path of the optical fiber 59 along the lower surface 54 of the baseplate is shown in more detail in FIG. 3. The optical fiber 59 follows a curved path advantageously passing alongside each of the semiconductor power components 37, in order to measure the temperature.

The elongated sensor 58 is for example a fiber-optic temperature sensor with a Bragg network optical fiber sensor or a Rayleigh backscattering optical fiber sensor.

According to a variant not shown, the sensor 58 may comprise several optical fibers spreading along the lower surface 54 along paths different from each other.

Each optical fiber 59 advantageously has an outer diameter below 100 μm and has a suitable profile so that the fiber may have a radius of curvature less than or equal to 5 mm. This allows the optical fiber 59 to follow a tortuous path following close to the components 37.

Recall that the principal of a Bragg network fiber consists of locally changing the index of refraction of the core of the fiber thus creating a series of networks (Bragg networks). Each network reflects a wavelength that is specific and different from other networks. Each network serves to locally measure a temperature. It is therefore possible to measure a multitude of temperature points on a single optical fiber.

Recall also that a Raleigh backscattering fiber takes advantage of the imperfections intrinsically present in the fiber (due to heterogeneities generated during the fabrication). These imperfections lead to backscattering all along the fiber (similar to the presence of weakly reflecting mirrors along the fiber). The use of this backscattered signal serves to measure a physical phenomenon (temperature or deformation) and the localization thereof.

Both these types of fiber are simultaneously sensitive to temperature and deformation. The close integration of the fiber 59 in the metal structure 56 serves to block the deformations of the fiber 59 assuring that the measured signal corresponds only to a temperature variation.

A fabrication method for the power module 31 will now be described. The method comprises a preliminary step of supplying and assembling the substrate 33 and the baseplate 49 which will not be further described because it is well known in the state of the art.

The method comprises a step of attachment of a part of the elongated sensor 58, for example of the optical fiber 59, on the lower surface 54.

The optical fiber 59 is advantageously housed in a protective capillary, in particular in a metal capillary, like a copper capillary.

The optical fiber 59 is for example attached by adhesive.

The optical fiber 59 follows a path on the lower surface 54 after advantageously passing alongside each of the components 37.

In the case where the optical fiber 59 is housed in a nonmetallic capillary, the method comprises a step of depositing a thin metallization layer on said capillary. The thin layer has a thickness of a few microns and is formed according to a conventional method by cathodic powdering, evaporation or vaporization, for example. This thin layer allows the formation of the metal structure on the capillary in the following step.

The method then comprises a step of formation of the metal structure 56, here a metal plate of substantially constant thickness.

The metal structure 56 is formed by electrodeposition, on the lower surface 54 and the optical fiber 59, in an electrolytic bath in order to immerse said optical fiber in said metal structure 56. This makes it possible to have an excellent thermal contact between the metal structure 56 and the optical fiber 59, in that way assuring the mechanical hold on the optical fiber 59. Subsequent to the formation of the metal plate 56, a radiator 53 is attached to said metal plate 56, on the side opposite the baseplate 49, for example by means of a thermal interface material 55.

A power module 31 according to a second embodiment of the invention is shown in FIG. 4. This power module 31 is identical to the one previously described, except for the following.

In this embodiment, the elongated sensor 58 comprises a plurality of thermocouples 62, in particular as many thermocouples as components 37, connected to a control module 64. The thermocouples 62 are advantageously located alongside each of the components 37 near the lower surface 54 of the baseplate 49 and immersed in the electrodeposited metal layer.

The fabrication method for this power module 31 is similar to the previous method, with elongated sensors of a different kind.

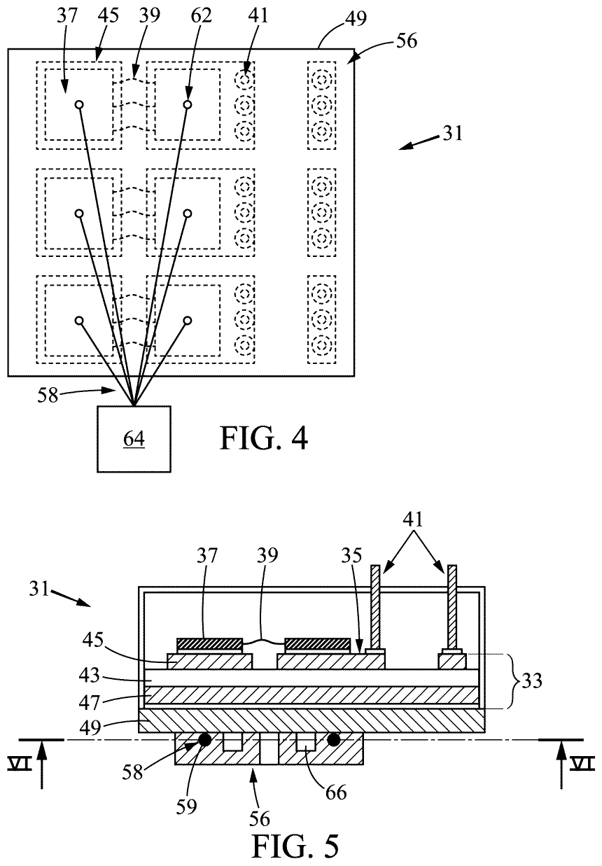

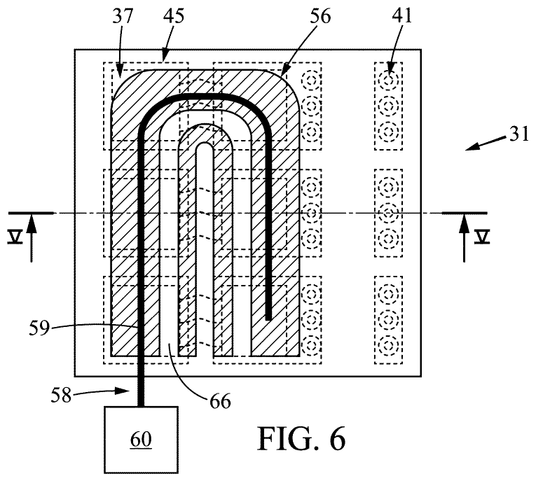

A power module 31 according to a third embodiment of the invention is shown in FIGS. 5 and 6.

This power module 31 is identical to the module according to the first embodiment of the invention, except for the following.

In the third embodiment, the metal structure 56 is a thermal radiator formed directly by electrodeposition on the lower surface 54 of the baseplate 49 in which the optical fiber 59 for the elongated sensor 58 is immersed.

The metal radiator has a U-shape elongated in a plane parallel to the lower surface 54, as shown in FIG. 6 and spreads alongside each of the components 37.

The radiator has a substantially rectangular outer section in a plane transverse to the spread thereof, as shown in FIG. 5. The height of the radiator, measured perpendicular to the lower surface 54, is for example included between 10 μm and 10 mm.

The radiator defines a central channel 66 intended to receive the circulation of a cooling fluid, and to improve thermal dissipation. The inner channel 66 has for example a square or rectangular cross-section. The dimensions of the section of the inner channel 66 are for example included between 10 μm and 10 mm.

The radiator is for example made of copper, or alternatively a copper alloy, or any other metal compatible with electrodeposition.

The fabrication method of the power module 31 according to the third embodiment is now going to be described, identical to the fabrication method of the power module according to the first embodiment except for the following.

The method comprises a preliminary step of fabrication of a preform intended to shape the radiator.

The preform is for example a long element which reproduces the shape of the inner channel 66 such that the preform constitutes a negative of the final shape of the radiator.

The preform is for example made by additive fabrication from a polymer material.

The preform is then fixed to the lower surface and covered with a thin metallization layer. The thin layer has a thickness of a few microns and is formed according to a conventional method by cathodic powdering, evaporation or vaporization, for example. This thin layer allows the formation of the metal structure on the preform by electrodeposition.

A mask is then applied on a part of the lower surface 54 on which the radiator is not intended to spread. The mask is for example a polymer film, onto which electrodeposition is impossible. The elongated sensor 58 is then placed on a region of the lower surface onto which the radiator is going to be formed, and could be metallized if necessary, as previously described.

The radiator is then formed by electrodeposition in an electrolytic bath on the unmasked region of the lower surface 54, on the preform and on the elongated sensor 58, until the desired metal thickness is deposited for forming the radiator with the intended height.

The preform and the mask are then withdrawn, either mechanically when that is possible, or by chemical and/or thermal dissolution.

According to a variant, the methods according to the two embodiments described may be implemented on a power module that does not comprise a baseplate; the metal structure 56 is deposited directly on the lower metallization 47 of the substrate 33.

1. A power module (31) comprising:
a plurality of semiconductor-based power components (37);
a substrate (33) comprising an upper metallization (45) receiving the components (37) and a lower metallization (47) opposite to the upper metallization (45);
a metal structure (56) in direct contact with a lower surface (54) defined by a baseplate (49) fixed to the lower metallization (47) of the substrate (33) or by the lower metallization (47) of the substrate (33), on the side opposite the components (37); and
at least one elongated temperature sensor (58), at least partially immersed in the metal structure (56) and spreading parallel to the lower surface (54);
wherein the metal structure (56) is formed by electrodeposition on the lower surface (54) and the elongated sensor (58).

2. The power module (31) according to claim 1, wherein the metal structure (56) is a plate spreading over at least one part of the lower surface (54), where the plate has a thickness, measured perpendicular to said lower surface (54), that is substantially constant over the spread thereof.

3. The power module (31) according to claim 1, wherein the metal structure (56) is a thermal radiator spreading over at least a portion of the lower surface (54).

4. The power module (31) according to claim 1, wherein each elongated sensor (58) comprises an optical fiber (59), and in particular is a Bragg network optical fiber sensor or a Rayleigh backscattering optical fiber sensor.

5. The power module (31) according to claim 4, wherein each optical fiber (59) has an outer diameter below 100 μm and has a suitable profile so that the optical fiber (59) has a radius of curvature less than or equal to 5 mm.

6. The power module (31) according to claim 1, wherein each elongated sensor (58) comprises at least one thermocouple.

7. A fabrication method for a power module (31) according to claim 1, where the method comprises the following steps:
supplying a substrate (33) having an upper metallization (45) intended to receive semiconductor power components (37) and a lower metallization (47) opposite the upper metallization, and optionally a baseplate (49) attached to the lower metallization of the substrate, where the baseplate (49) or the substrate has a lower surface opposite the components (37);
placement of at least one elongated sensor (58) on the lower surface (54);
formation of the metal structure (56) by electrodeposition on the lower surface (54) and on the elongated sensor (58).

8. The method according to claim 7, wherein the metal structure (56) is a plate of substantially constant thickness, where the method further comprises a step of attachment of a radiator (53) to the plate on the side opposite the lower surface (54).

9. The method according to claim 7 wherein the metal structure (56) is a thermal radiator in which each elongated sensor (58) is at least in part immersed, where the method comprises the steps of:
preparation, in particular by additive fabrication, of a preform suited for shaping the thermal radiator;
placement of the preform on the lower surface (54) and, optionally, placement of a mask on a portion of the lower surface (54); and
subsequent to the formation of the metal structure (56), withdrawal of the preform and, as applicable, the mask.

10. The power module (31) according to claim 2, wherein each elongated sensor (58) comprises an optical fiber (59), and in particular is a Bragg network optical fiber sensor or a Rayleigh backscattering optical fiber sensor.

11. The power module (31) according to claim 10, wherein each optical fiber (59) has an outer diameter below 100 μm and has a suitable profile so that the optical fiber (59) has a radius of curvature less than or equal to 5 mm.

12. The power module (31) according to claim 2, wherein each elongated sensor (58) comprises at least one thermocouple.

13. A fabrication method for a power module (31) according to claim 2, where the method comprises the following steps:
supplying a substrate (33) having an upper metallization (45) intended to receive semiconductor power components (37) and a lower metallization (47) opposite the upper metallization, and optionally a baseplate (49) attached to the lower metallization of the substrate, where the baseplate (49) or the substrate has a lower surface opposite the components (37);
placement of at least one elongated sensor (58) on the lower surface (54);
formation of the metal structure (56) by electrodeposition on the lower surface (54) and on the elongated sensor (58).
